(19) United States
(12) Patent Application Publication
(10) Pub. No.: US 2015/0107510 A1
(43) Pub. Date: Apr. 23, 2015

(54) COATING A SUBSTRATE WEB BY ATOMIC LAYER DEPOSITION

(71) Applicant: Sven Lindfors, Espoo (FI)

(72) Inventor: Sven Lindfors, Espoo (FI)

(73) Assignee: Picosun Oy, Espoo (FI)

(21) Appl. No.: 14/407,956

(22) PCT Filed: Jun. 15, 2012
(86) PCT No.: PCT/FI2012/050616

§ 371 Date: Dec. 14, 2014

(51) Int. Cl. C30B 25/02; C30B 25/14; C30B 25/12

(52) U.S. Cl. CPC C30B 25/025; C30B 25/12; C30B 25/14
USPC 117/98; 118/718

(57) ABSTRACT

The present invention relates to a method of receiving and treating a moving substrate web (110) in a reaction space of an atomic layer deposition (ALD) reactor (100) and apparatuses therefore. It also pertains to a production line that includes such a reactor. The invention comprises receiving a moving substrate web into a reaction space (150) of an atomic layer deposition reactor, providing a track for the substrate web with a repeating pattern (140) in the reaction space and exposing the reaction space to precursor pulses to deposit material on the substrate web by sequential self-saturating surface reactions. The pattern is performed by turning the direction of propagation of the substrate web a plurality of times in the reaction space. One effect of the invention is adjusting an ALD reactor to a required production line substrate web speed.

### FIELD OF THE INVENTION

The present invention generally relates to deposition reactors. More particularly, the invention relates to atomic layer deposition reactors in which material is deposited on surfaces by sequential self-saturating surface reactions.

### BACKGROUND OF THE INVENTION

Atomic Layer Epitaxy (ALE) method was invented by Dr. Tuomo Suntola in the early 1970's. Another generic name for the method is Atomic Layer Deposition (ALD) and it is nowadays used instead of ALE. ALD is a special chemical deposition method based on the sequential introduction of at least two reactive precursor species to at least one substrate.

Thin films grown by ALD are dense, pinhole free and have uniform thickness. For example, in an experiment aluminum oxide has been grown by thermal ALD from trimethylaluminum (CH₃)₃Al, also referred to as TMA, and water at 250-300° C. resulting in only about 1% non-uniformity over a substrate wafer.

Until now the ALD industry has mainly concentrated on depositing material on one or more rigid substrates. In recent years, however, an increasing interest has been shown towards roll-to-roll ALD processes in which material is deposited on a substrate web unwound from a first roll and wound up around a second roll after deposition.

### SUMMARY

A concurrently filed patent application PCT/FI2012/xxxxxx of the same assignee discloses ALD reactors for depositing material on a substrate web where the material growth is controlled by the speed of the web. The substrate web is moved along a straight track through a processing chamber and a desired thin film coating is grown onto the substrate surface by a temporally divided ALD process.

A production line is known in that a substrate web should usually be driven at a predetermined constant speed. Then there is usually not possible to control the thickness of deposited material by varying the speed of the web.

Each deposition cycle typically produces one layer of coating. It has been observed that depending on various factors such as the size of the processing chamber of an ALD reactor a deposition cycle has a minimum time. Further it has been observed that for a desired coating within a processing chamber a considerable amount of cycles may be needed. To obtain this with an in-line ALD reactor, requires very slow speed of the substrate web (or a very long processing chamber, which is not practicable). The low speed requirement is in contrast to the typically prevailing high speed requirement of a production line.

According to a first example aspect of the invention there is provided a method comprising:

receiving a moving substrate web into a reaction space of an atomic layer deposition reactor;
providing for the substrate web a track with a repeating pattern in the reaction space; and
exposing the substrate web to temporally separated precursor pulses in said reaction space to deposit material on said substrate web by sequential self-saturating surface reactions.

In certain example embodiments, the method comprises:

turning the direction of propagation of the substrate web a plurality of times to form said repeated pattern.

The turning may be implemented by turning units, such as rolls. The rolls (turning rolls) may be attached to the reaction space. Alternatively, the turning units may be placed into a processing chamber providing said reaction space, but outside of the actual reaction space, into a turning unit volume (or a shield volume). In such an embodiment, an intermediate plane may divide the processing chamber into the reaction space and the turning unit volume (which may reside in both sides of the reaction space). The turning unit volume may be an excess pressure volume compared to the pressure in the reaction space.

The turning may be implemented by exact 180 degree turns or substantially 180 degree turns. The repeating pattern then basically comprises a portion of track heading in one direction, and the following portion heading into the opposite direction (for example, up and down). Alternatively, the turning may be more or less than 180 degrees. In other embodiments, more complex repeating patterns may be present.

In certain example embodiments, the method comprises:

receiving the substrate web through an input gate that prevents gases from escaping from the reaction space.

In certain example embodiments, the input gate is formed by a slit that maintains a pressure difference between the reaction space and an excess pressure volume on the other side of the slit. The excess pressure herein means that although the pressure in the excess pressure volume is a reduced pressure with regard to the ambient (or room) pressure, it is a pressure higher compared to the pressure in the reaction space. Inactive gas may be fed into the excess pressure volume to maintain said pressure difference. Accordingly, in certain example embodiments, the method comprises:

feeding inactive gas into the excess pressure volume.

In certain example embodiments, the slit (input slit) is so thin that the substrate web just hardly fits to pass through. The excess pressure volume may be a volume in which the first (or source) roll resides. In certain example embodiments, both the first and second roll reside in the excess pressure volume. The excess pressure volume may be denoted as an excess pressure space or compartment. The slit may operate as a flow restrictor, allowing inactive gas to flow from said excess pressure volume to the reaction space (or processing chamber), but substantially preventing any flow in the other direction (i.e., from reaction space to the excess pressure volume). The slit may be a throttle. The slit may operate as a constriction for the inactive gas flow.

In certain example embodiments, the reactor comprises constriction plates forming said slit. The constriction plates may be two plates placed next to each other so that the substrate web just hardly fits to pass through. The plates may be parallel plates so that the space between the plates (slit volume) becomes elongated in the web moving direction.

The substrate web may be unwound from the first roll, ALD processed in a processing chamber providing the reaction space, and wound up on the second roll.

The ALD processed substrate web may output from the reaction space via an output gate. In certain example embodiments, the output gate is formed by a second slit (output slit) that maintains a pressure difference between the reaction space and an excess pressure volume on the other side of the slit. The structure and function of the second slit may correspond to that of the first mentioned slit.

The second slit may reside on the other side of the reaction space compared to the first mentioned slit.

In certain example embodiments, the input gate comprises an input port and an input slit connected by a hallway. The hallway may be an excess pressure hallway maintaining a pressure difference between the input gate and the reaction space. Accordingly, in certain example embodiments, the method comprises:

receiving the substrate web through an excess pressure hallway.

The purpose of the excess pressure hallway may be to prevent precursor vapor/reactive gases from flowing to the outside of the reaction space via the substrate web route. Inactive gas may be fed into the excess pressure hallway.

The output gate, in certain example embodiments, comprises an output slit and an output port connected by a hallway. The hallway may be an excess pressure hallway. Inactive gas may be fed into the excess pressure hallway to maintain the pressure difference.

In certain example embodiments, said track with the repeating pattern forms flow channels within the reaction space, the method comprising:

using a flow distributor for said precursor pulses to reach each of said flow channels.

In certain example embodiments, said flow distributor comprises a flow spreader with a plurality of flow rakes with in-feed head openings (apertures). The openings may be at the point of the corresponding flow channels. The flow spreader may be a vertical flow spreader. The flow rakes may be straight channels. The flow rakes are in fluid communication with the flow spreader.

The flow distributor may reside on one side of the track on its side and an exhaust line on the other side of the track.

In certain example embodiments, the method comprises:

adjusting the length of the track within the reaction space by adjusting the track pattern. This may be achieved in certain example embodiments by driving the substrate web only via a subset of the turning units. In other words, the method in certain example embodiments comprises skipping one or more turning units. Since the length of the track affects the thickness of the coating, the obtained thickness may be adjusted by adjusting the track pattern.

In certain example embodiments, the whole reaction space is alternately exposed to precursor pulses. Accordingly, the exposure of the reaction space to a precursor pulse of a first precursor may occur in the exactly same space (or same volume of a processing chamber) as the exposure to a precursor pulse of a second (another) precursor. The ALD process in the reaction space is temporally divided (or time-divided) in contrast to e.g. spatial ALD which requires a reaction space to be spatially divided. The substrate web may be continuously moved or periodically moved (e.g., in a stop and go fashion) through the reaction space. The material growth occurs when the substrate web is within the reaction space and is alternately exposed to precursor vapor pulses to cause sequential self-saturating surface reactions to occur on the substrate web surface. When the substrate web is outside the reaction space in the reactor, substrate web surface is merely exposed to inactive gas, and ALD reactions do not occur.

The reactor can comprise a single processing chamber providing said reaction space. In certain example embodiments, the substrate web is driven from a substrate web source, such as a source roll, into the processing chamber (or reaction space). The substrate web is processed by ALD reactions in the processing chamber and driven out of the processing chamber to a substrate web destination, such as a destination roll. When the substrate web source and destination are rolls, a roll-to-roll atomic layer deposition method is present. The substrate web may be unwound from a first roll, driven into the processing chamber, and wound up around a second roll after deposition. Accordingly, the substrate web may be driven from a first roll to a second roll and exposed to ALD reactions on its way. The substrate web may be bendable. The substrate web may also be rollable. The substrate web may be a foil, such as a metal foil.

The web may be driven continuously from said first roll onto the second roll. In certain example embodiment, the web is driven continuously at constant speed. In certain example embodiment, the web is driven by a stop and go fashion. Then the substrate web may be stopped for a deposition cycle, moved upon the end of the cycle, and stopped for the next cycle, and so on. Accordingly, the substrate web may be moved from time to time at predetermined time instants.

According to a second example aspect of the invention there is provided an apparatus, comprising:

an input gate configured to receive a moving substrate web into a reaction space of an atomic layer deposition reactor;
track forming elements configured to provide for the substrate web a track with a repeating pattern in the reaction space; and
a precursor vapor feeding part configured to expose the substrate web to temporally separated precursor pulses in said reaction space to deposit material on said substrate web by sequential self-saturating surface reactions.

The apparatus may be an atomic layer deposition (ALD) reactor. The ALD reactor (or reactor module) may be a standalone apparatus or a part of a production line. A driving unit may be configured to drive the substrate web from a first roll via the reaction space to a second roll. The driving unit may be connected to the second (destination) roll. In certain example embodiments, the driving unit comprises a first drive that is connected to the first (source) roll and a second drive that is connected to the second (destination) roll, respectively. The driving unit may be configured to rotate the roll(s) at a desired speed.

In certain example embodiments, the apparatus comprises:

turning units configured to turn the direction of propagation of the substrate web a plurality of times to form said repeated pattern.

In certain example embodiments, the apparatus comprises:

an input gate configured to receive the substrate web therethrough into the reaction space, the input gate being configured to prevent gases from escaping from the reaction space.

In certain example embodiments, the input gate comprises an excess pressure hallway through which the substrate web is configured to travel.

In certain example embodiments, said track with the repeating pattern is configured to form flow channels within the reaction space, and the apparatus comprises:

a flow distributor for said precursor pulses to reach each of said flow channels.

In certain example embodiments, said flow distributor comprises a flow spreader with a plurality of flow rakes with in-feed head openings.

According to a third example aspect of the invention there is provided a production line, comprising the apparatus of the second aspect or its embodiments configured to perform the method according to the first aspect or its embodiments.

According to a fourth example aspect of the invention there is provided an apparatus comprising:

input means for receiving a moving substrate web into a reaction space of an atomic layer deposition reactor;
track forming means for providing for the substrate web a track with a repeating pattern in the reaction space; and
precursor vapor feeding means for exposing the substrate web to temporally separated precursor pulses in said reaction space to deposit material on said substrate web by sequential self-saturating surface reactions.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The invention will now be described, by way of example only, with reference to the accompanying drawings, in which:

FIG. 1 shows a side view of a modular deposition reactor in accordance with an example embodiment;

FIG. 2 shows a side view of a production line in accordance with an example embodiment;

FIG. 3 shows a top view of another deposition reactor in accordance with an example embodiment;

FIG. 4 shows a standalone deposition reactor in accordance with an example embodiment;

FIG. 5 shows another standalone deposition reactor in accordance with an example embodiment; and

FIG. 6 shows a rough block diagram of a deposition reactor control system in accordance with an example embodiment.

### DETAILED DESCRIPTION

In the following description, Atomic Layer Deposition (ALD) technology is used as an example. The basics of an ALD growth mechanism are known to a skilled person. As mentioned in the introductory portion of this patent application, ALD is a special chemical deposition method based on the sequential introduction of at least two reactive precursor species to at least one substrate. The substrate, or the moving substrate web in this case, is located within a reaction space. The reaction space is typically heated. The basic growth mechanism of ALD relies on the bond strength differences between chemical adsorption (chemisorption) and physical adsorption (physisorption). ALD utilizes chemisorption and eliminates physisorption during the deposition process. During chemisorption a strong chemical bond is formed between atom(s) of a solid phase surface and a molecule that is arriving from the gas phase. Bonding by physisorption is much weaker because only van der Waals forces are involved.

The reaction space of an ALD reactor comprises all the typically heated surfaces that can be exposed alternately and sequentially to each of the ALD precursor used for the deposition of thin films or coatings. A basic ALD deposition cycle consists of four sequential steps: pulse A, purge A, pulse B and purge B. Pulse A typically consists of metal precursor vapor and pulse B of non-metal precursor vapor, especially nitrogen or oxygen precursor vapor. Inactive gas, such as nitrogen or argon, and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness.

In a typical ALD process, precursor species form through chemisorption a chemical bond to reactive sites of the heated surfaces. Conditions are typically arranged in such a way that no more than a molecular monolayer of a solid material forms on the surfaces during one precursor pulse. The growth process is thus self-terminating or saturative. For example, the first precursor can include ligands that remain attached to the adsorbed species and saturate the surface, which prevents further chemisorption. Reaction space temperature is maintained above condensation temperatures and below thermal decomposition temperatures of the utilized precursors such that the precursor molecule species chemisorb on the substrate(s) essentially intact. Essentially intact means that volatile ligands may come off the precursor molecule when the precursor molecules species chemisorb on the surface. The surface becomes essentially saturated with the first type of reactive sites, i.e. adsorbed species of the first precursor molecules. This chemisorption step is typically followed by a first purge step (purge A) wherein the excess first precursor and possible reaction by-products are removed from the reaction space. Second precursor vapor is then introduced into the reaction space. Second precursor molecules typically react with the adsorbed species of the first precursor molecules, thereby forming the desired thin film material or coating. This growth terminates once the entire amount of the adsorbed first precursor has been consumed and the surface has essentially been saturated with the second type of reactive sites. The excess of second precursor vapor and possible reaction by-product vapors are then removed by a second purge step (purge B). The cycle is then repeated until the film or coating has grown to a desired thickness. Deposition cycles can also be more complex. For example, the cycles can include three or more reactant vapor pulses separated by purging steps. All these deposition cycles form a timed deposition sequence that is controlled by a logic unit or a microprocessor.

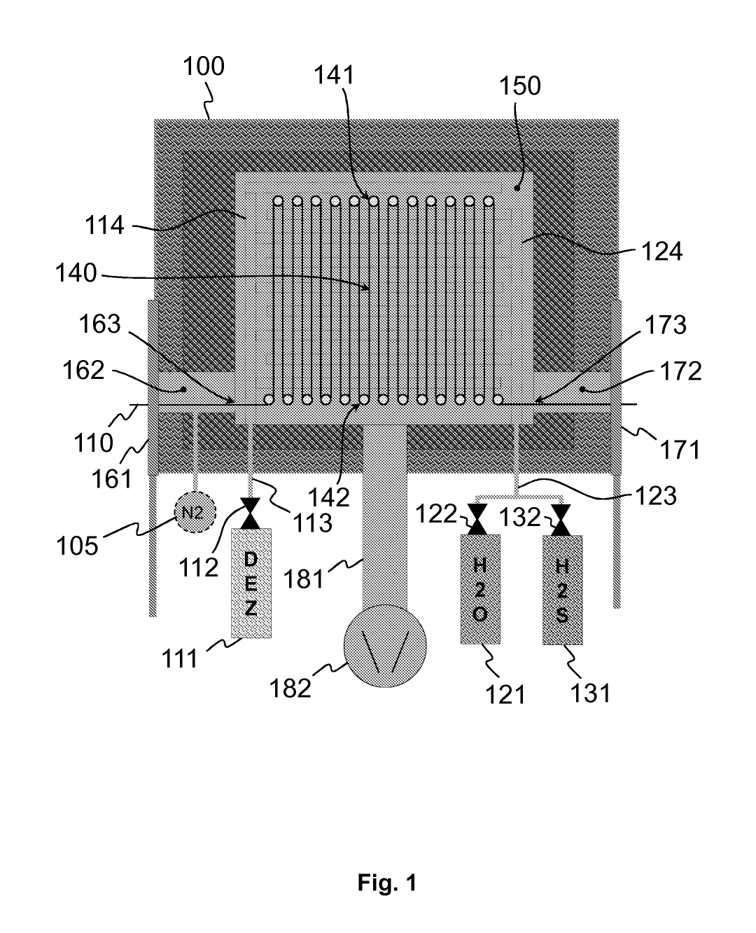

FIG. 1 shows a side view of a modular deposition reactor in accordance with an example embodiment. The deposition reactor 100 may form part of a production line. A substrate web 110 is received into the deposition reactor 100 via an input port 161. The route of the substrate web 110 continues through a hallway 162 via a first slit 163 into a reaction space 150. The reaction space 150 provides for the substrate web 110 a track with a repeating pattern 140. The reaction space 150 comprises a first row of rolls 141 in the top section of the reaction space 150 and a second row of rolls 142 in the bottom section of the reaction space 150. The direction of propagation of the substrate web 110 is turned by the rolls 141 and 142 to form said repeated pattern. The repeating pattern then comprises a portion of track heading in one direction, and the following portion heading into the opposite direction (here: up and down).

The deposition reactor 100 comprises a first precursor source 111 (here: DEZ, diethylzinc), and a second precursor source 121 (here: H₂O, water). In this and in other embodiments, the water source can be replaced by an ozone source. A first pulsing valve 112 controls the flow of precursor vapor of the first precursor into a first precursor in-feed line 113. A second pulsing valve 122 controls the flow of precursor vapor of the second precursor into a second precursor in-feed line 123. The in-feed line 113 continues in the reaction space 150 as a first flow distributor 114, and the in-feed line 123 as a second flow distributor 124. The deposition reactor 100, in this example embodiment, also comprises a third precursor source 131 (here: H₂S, hydrogen sulfide). A third pulsing valve 132 controls flow of precursor vapor of the third precursor into a third precursor in-feed line 123. In this example embodiment, the third and second precursor share the same in-feed line 123.

The flow distributor 114 comprises a vertical spreader in fluid communication with a plurality of flow rakes. The flow rakes may be straight horizontal flow channels with apertures. Each flow rake is in fluid communication with the reaction space 150 through the (plurality of) apertures. The flow distributor 124 has a similar structure. The first and second flow distributors 114, 124 can be interspersed so that they can be placed to the same level on a side of the reaction space 150.

The track with the repeating pattern forms lateral flow channels within the reaction space 150. The flow channels are formed in between the bending substrate web surface. The flow rakes contain apertures at the points of the flow channels so that precursor vapor flows via the apertures into the flow channels. The other side of the reaction space 150 comprises an exhaust line 181 that collects the gases and directs them downwards to a vacuum pump 182.

In the reaction space, the substrate web is exposed to ALD reactions. A deposition sequence is formed of one or more consecutive deposition cycles, each cycle consisting of at least a first precursor exposure period (pulse A) followed by a first purge step (purge A) followed by a second precursor exposure period (pulse B) followed by a second purge step (purge B). In the event of three precursors, a deposition cycle may further contain a third precursor exposure period (pulse C) followed by a third purge step (purge C). Or in a more complex case purge B may be followed by another first precursor exposure period followed by a purge step followed by a third precursor exposure period followed by a purge step.

During a precursor exposure period precursor vapor flows into the reaction space 150 via one of the flow distributors 114, 124 and remaining gases exit the reaction space 150 via the exhaust guide 181. Inactive gas (such as nitrogen) flows via the other flow distributor(s). During purge steps only inactive gas flows into the reaction space 150.

The substrate web exits the reaction space 150 via an output slit 173 on the opposite side of the reaction space 150. It continues through a hallway 172 and via an output port 171 to the next step of the production line process.

The input port 161, hallway 162 and input slit 163 form an example of an input gate. Similarly, the output slit 173, hallway 172 and output port 171 form an example of an output gate. The purpose of the gates is to prevent gases from escaping from the reaction space 150 via the substrate web route.

The slits 163 and 173, in certain example embodiments, function as throttles maintaining a pressure difference between the reaction space 150 and the hallways 162 and 172. Also, in order to maintain the pressure difference, inactive gas may be fed to one or both of the hallways 162 and 172. FIG. 1 shows feeding inactive gas from an inactive gas source 105 into the hallway 162. In the deposition reactor shown in FIG. 1, the pressure within the (excess pressure) hallways 162 and 172 is higher than the pressure within the reaction space 150. As an example, the pressure within the reaction space 150 may be 1 mbar while the pressure within the hallways 162 and 172 is for example 5 mbar. The pressure difference forms a barrier preventing a flow from the reaction space 150 into the hallways 162 and 172. Due to the pressure difference, however, flow from the other direction (that is, from hallways 162 and 172 to the reaction space 150 through the slits 163 and 173 is possible). As to the inactive gas flowing from flow distributors 114 and 124 (as well as precursor vapor during precursor vapor pulse periods), these flows therefore practically only see the vacuum pump 182.

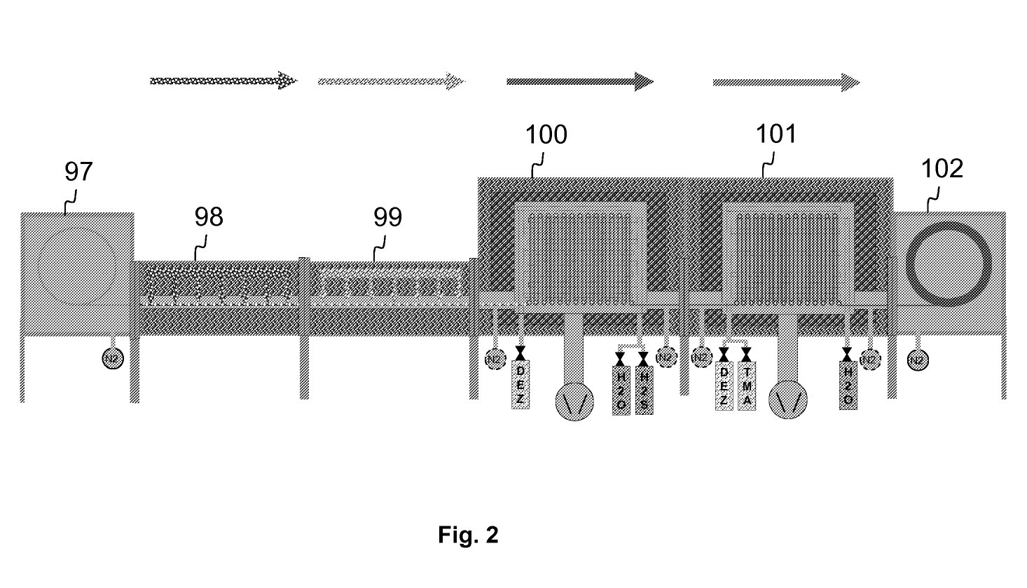

FIG. 2 shows a side view of a production line in accordance with an example embodiment. In an example embodiment, the production line is for coating a stainless steel (SS) foil for solar cell industry purposes, for example. The SS foil is driven from a source roll module 97 to a destination roll module 102 via a plurality of processing modules 98-101. The first module (source roll module) 97 of the production line comprises a source SS foil roll within an inactive gas volume which is unwound. Inactive gas (here: N₂) is conducted to the space where the roll resides from an inactive gas source.

The unwound SS foil then enters the next module 98 of the production line. In this example embodiment, the module 98 is a molybdenum (Mo) sputtering module. After molybdenum processing/deposition the SS foil enters the next module 99 of the production line. In this example embodiment, the module 99 is a copper indium gallium diselenide (CIGS) sputtering module.

After CIGS processing/deposition the SS foil enters the next module 100 of the production line. In this example embodiment, the module 100 is the ALD reactor module of FIG. 1. In this module, a desired amount of ZnOS is deposited on the SS foil. If desired, inactive gas may be conducted to the hallways of module 100 to strengthen a barrier preventing gas from flowing from the reaction space into one or both of the hallways. The length of the track within the reaction space of module 100 is arranged so that the desired thickness of coating is obtained. This can be arranged by using a suitable amount of track turning units (here: rolls) around which the track turns. The number of turns can be adjusted, for example, by skipping one or more rolls. In this way, the ALD reactor module 100 can adjust to the predetermined substrate web speed of the production line.

After ZNOS deposition the SS foil enters the next module 101 of the production line. In this example embodiment, the module 101 is another ALD reactor module. The ALD module 101 basically corresponds to the module 100 except that the sources used in the ALD process are different. In this module, a desired amount of ZnO:Al is deposited on the SS foil. If desired, inactive gas may be conducted to one or both of the hallways of module 101 and/or the track length adjusted similarly as in module 100.

From module 101 the coated SS foil enters a destination roll module 102. The SS foil is wound up around a destination roll. Inactive gas is conducted to the space where the roll resides from an inactive gas source.

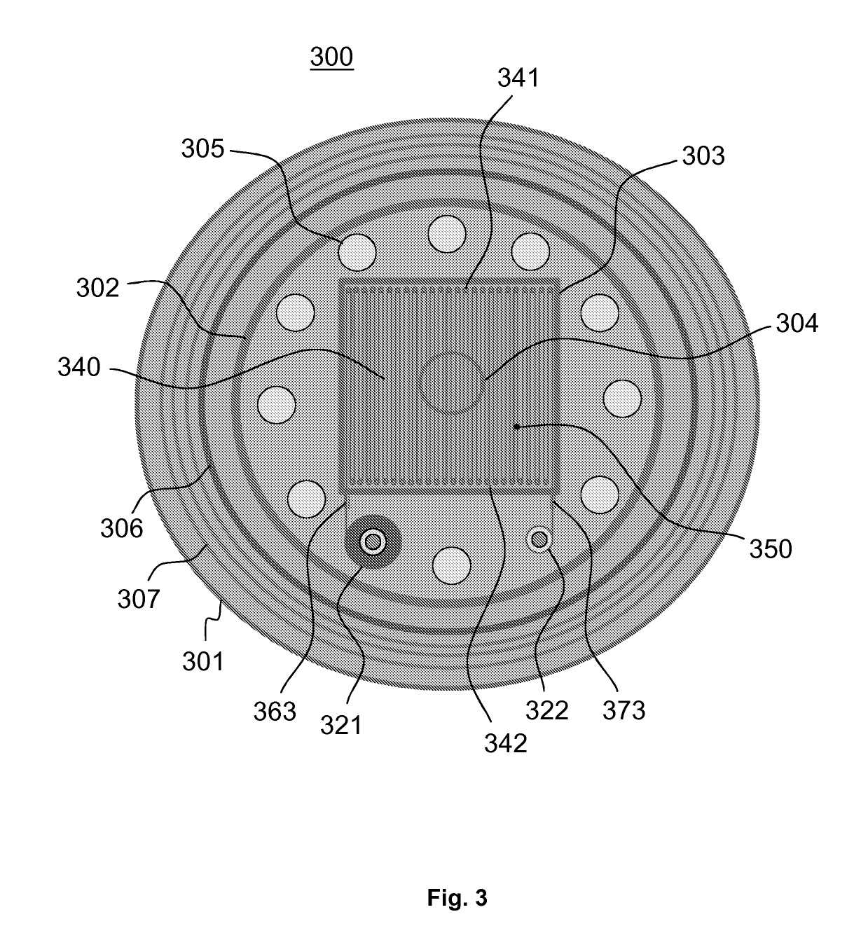

FIG. 3 shows a top view of another deposition reactor in accordance with an example embodiment. The deposition reactor 300 comprises a cylindrical reaction chamber 302 within a vacuum chamber 301, which also is cylindrical in this embodiment. Around the reaction chamber 302 is an intermediate space comprising heat reflectors 307 and a reaction chamber heater 306. A rotating axis of a source roll 321 of a rollable substrate web is attached to a bottom feed-through 305 of the reaction and vacuum chambers. A rotating axis of a destination roll 322 of the rollable substrate web is attached to another bottom feed-through 305 of the reaction and vacuum chambers. The substrate web is input into a processing chamber 303 within the reaction chamber 302 through an input slit 363. The processing chamber may have for example a rectangular or square cross-section. The processing chamber provides the substrate web a track with a repeating pattern 340 through turning the substrate web around a first row 341 and second row 342 of turning rolls. The repeating pattern may fill substantially the whole processing chamber. The interior of the processing chamber 303 forms a reaction space 350. The reaction space is alternately exposed to precursor vapor of precursors. The precursor vapor of precursors is fed into the reaction space 350 from the top of the processing chamber 303. The flow of precursor vapor is from top to bottom along the substrate web surface into an exhaust line 304 at the bottom of the processing chamber 303. The coated substrate web is output from the reaction space 350 through an output slit 373 and wound up around the destination roll 322.

The input and output slits 363 and 373 are so thin that precursor vapor does not exit from the reaction space through the slits, but a vacuum pump behind the exhaust line draws it to the exhaust line 304. In addition, an excess pressure volume can be arranged around the processing chamber 303 to the reaction chamber 302 by feeding inactive gas thereinto.

In certain example embodiments, the substrate web is moved continuously. In other example embodiments, the substrate web is moved in a stop and go fashion. The substrate web may lie still during a plurality of deposition cycles, then moved a predetermined amount, and then again lie still during a plurality of deposition cycles, and so on.

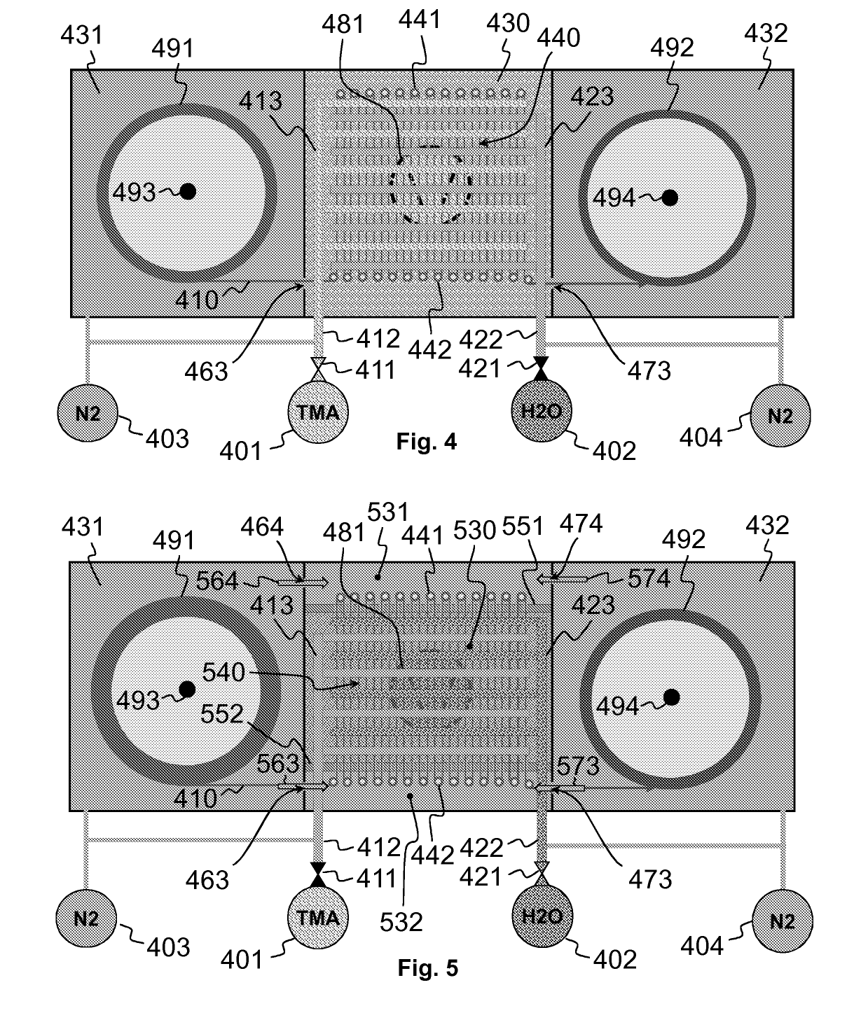

FIG. 4 shows a standalone deposition reactor in accordance with an example embodiment. A substrate web 410 is received into a reaction space 430 of the deposition reactor via an input slit 463 arranged into a processing chamber wall. The reaction space 430 provides for the substrate web 410 a track with a repeating pattern 440. The reaction space 430 comprises a first row of rolls 441 in a first side section of the reaction space 430 and a second row of rolls 442 in the opposite side section of the reaction space 430. The direction of propagation of the substrate web 410 is turned by the rolls 441 and 442 to form said repeated pattern. The repeating pattern then comprises a portion of track heading in one direction, and the following portion heading into the opposite direction (here: from side to side). The number of turns can be adjusted, for example, by skipping one or more rolls as in other embodiments.

The deposition reactor comprises a first precursor source 401 (here: TMA, trimethylaluminum), and a second precursor source 402 (here: H₂O, water). A first pulsing valve 411 controls the flow of precursor vapor of the first precursor into a first precursor in-feed line 412. A second pulsing valve 421 controls the flow of precursor vapor of the second precursor into a second precursor in-feed line 422. The in-feed line 412 continues in the reaction space 430 as a first flow distributor 413, and the in-feed line 422 as a second flow distributor 423.

The flow distributor 413 comprises a horizontal spreader in fluid communication with a plurality of flow rakes. The flow rakes may be straight horizontal flow channels with apertures. Each flow rake is in fluid communication with the reaction space 430 through the (plurality of) apertures. The flow distributor 423 has a similar structure. The first and second flow distributors 413, 423 can be interspersed so that they can be placed to the same level on a top side of the reaction space 430.

The track with the repeating pattern forms vertical flow channels within the reaction space 430. The flow channels are formed in between the bending substrate web surface. The flow rakes contain apertures at the points of the flow channels so that precursor vapor flows via the apertures into the flow channels. The other side at the bottom of the reaction space comprises an exhaust line 481 that collects the gases and directs them towards a vacuum pump (not shown).

In the reaction space, the substrate web is exposed to ALD reactions. A deposition sequence is formed of one or more consecutive deposition cycles, each cycle consisting of at least a first precursor exposure period (pulse A) followed by a first purge step (purge A) followed by a second precursor exposure period (pulse B) followed by a second purge step (purge B).

During a precursor exposure period precursor vapor flows into the reaction space 430 via one of the flow distributors 413, 423 and remaining gases exit the reaction space 430 via the exhaust guide 481. Inactive gas (such as nitrogen) flows via the other flow distributor. During purge steps only inactive gas flows into the reaction space 430.

The substrate web exits the reaction space 430 via an output slit 473 on the opposite side of the reaction space 430.

The deposition reactor comprises a source roll volume 431, a destination roll volume 432 and a processing chamber providing the reaction space 430 between the source and destination roll volumes. A source roll 491 in the source roll volume 431 is rotatable around a source roll axis 493 so that bendable substrate web in an example embodiment is unwound from the source roll and input to the reaction space 430. Similarly, a destination roll 492 in the destination roll volume 432 is rotatable around a destination roll axis 494 so that the bendable substrate web exiting the reaction space in an example embodiment is wound up around the destination roll 492.

The purpose of the slits 463 and 473 is to prevent gases from escaping from the reaction space 430 via the substrate web route.

The slits 463 and 473, in certain example embodiments, function as throttles maintaining a pressure difference between the reaction space 430 and the roll volumes 431 and 432. Also, in order to maintain the pressure difference, inactive gas may be fed to the roll volumes 431 and 432 from a first and a second inactive gas source 403 and 404, respectively. However, in other embodiments the inactive gas sources 403 and 404 may be implemented by a single inactive gas source. In the deposition reactor shown in FIG. 4, the pressure within the (excess pressure) roll volumes 431 and 432 is higher than the pressure within the reaction space 430. As an example, the pressure within the reaction space 430 may be 0.5 mbar while the pressure within the roll volumes 431 and 432 is for example 5 mbar. The pressure difference forms a barrier preventing a flow from the reaction space 430 into the roll volumes 431 and 432. Due to the pressure difference, however, flow from the other direction (that is, from the roll volumes 431 and 432 to the reaction space 430 through the slits 463 and 473 is possible). As to the inactive gas flowing from flow distributors 413 and 414 (as well as precursor vapor during precursor vapor pulse periods), these flows therefore practically only see the vacuum pump behind the exhaust line 481.

Moreover, FIG. 4 shows the deposition reactor during the first precursor exposure period. The first pulsing valve 411 is opened and precursor vapor of the first precursor flows into the reaction space 430 via the flow distributor 413 and through its apertures. Inactive gas flows into the reaction space 430 via the other flow distributor. ALD reactions occur on the substrate web surfaces. Remaining gases are evacuated into the exhaust line 481.

FIG. 5 shows another standalone deposition reactor in accordance with an example embodiment. The embodiment of FIG. 5 otherwise corresponds to the embodiment of FIG. 4 except that the turning units in the embodiment of FIG. 5 are placed into a processing chamber providing said reaction space, but outside of the actual reaction space, into a turning unit volume (or a shield volume). The processing chamber comprises a first intermediate plane 551 dividing the processing chamber into the reaction space 530 and a first turning unit volume 531. The processing chamber further comprises a second intermediate plane 552 dividing the processing chamber into the reaction space 530 and a second turning unit volume 532. The reaction space 530 therefore resides between the intermediate planes 551 and 552. The turning unit volumes 531 and 532 reside on the other side of the intermediate planes 551 and 552 in the edge areas of the processing chamber.

The substrate web 410 is able to go through the intermediate planes 551 and 552 to the turning units (rolls 441 and 442). There may be for example slits arranged in the intermediate planes 551 and 552. The track of the substrate web 410 therefore travels within the processing chamber both in the reaction space 540 and outside of the reaction space 430, in the turning unit volumes 531 and 532. ALD deposition only occurs within the reactions space 530, and the repeating pattern 540 appears in the reaction space 530 as in other embodiments.

The turning unit volumes 531 and 532 may be excess pressure volumes compared to the pressure in the reaction space 530. In the example embodiment of FIG. 5, inactive gas flows into the first turning unit volume 531 through a slit 464 arranged into the reaction chamber wall from the source roll volume 431 as depicted by arrow 564. Similarly, inactive gas flows into the first turning unit volume 531 through a slit 474 arranged into an opposite reaction chamber wall from the destination roll volume 432 as depicted by arrow 574. Inactive gas further flows into the second turning unit volume 532 through a processing chamber input slit 463 arranged into the reaction chamber wall from the source roll volume 431 as depicted by arrow 563. Similarly, inactive gas flows into the second turning unit volume 532 through a processing chamber output slit 473 arranged into an opposite reaction chamber wall from the destination roll volume 432 as depicted by arrow 573. A purpose of the excess pressure volume turning unit volumes 531 and 532 is to prevent reactive gases from flowing outside of the reaction chamber 530 via the intermediate planes 551 and 552.

The substrate web 410 is input into the second turning unit volume 532 via the processing chamber input slit 463 and therefrom to the processing chamber via a slit arranged into the intermediate plane 552. After ALD processing, the coated substrate web 410 is output from the reaction space 530 into the second turning unit volume 532 via a slit arranged into the intermediate plane 552 and therefrom to the destination roll volume 432 via the processing chamber output slit 473.

Moreover, FIG. 5 shows the deposition reactor during the second precursor exposure period. The second pulsing valve 421 is opened and precursor vapor of the second precursor flows into the reaction space 530 via the flow distributor 423 and through its apertures. Inactive gas flows into the reaction space 530 via the other flow distributor. ALD reactions occur on the substrate web surfaces. Remaining gases are evacuated into the exhaust line 481.

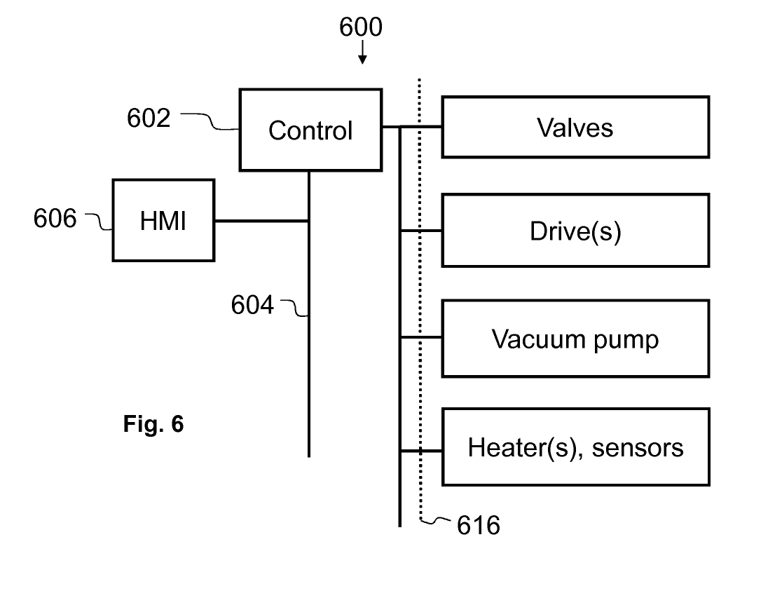

In an example embodiment, the deposition reactor (or reactors) described herein is a computer-controlled system. A computer program stored into a memory of the system comprises instructions, which upon execution by at least one processor of the system cause the deposition reactor to operate as instructed. The instructions may be in the form of computer-readable program code. FIG. 6 shows a rough block diagram of a deposition reactor control system 600. In a basic system setup process parameters are programmed with the aid of software and instructions are executed with a human machine interface (HMI) terminal 606 and downloaded via a communication bus 604, such as Ethernet bus or similar, to a control box 602 (control unit). In an embodiment, the control box 602 comprises a general purpose programmable logic control (PLC) unit. The control box 602 comprises at least one microprocessor for executing control box software comprising program code stored in a memory, dynamic and static memories, I/O modules, ND and D/A converters and power relays. The control box 602 sends electrical power to pneumatic controllers of appropriate valves of the deposition reactor. The control box controls the operation of drive(s) driving the web, the vacuum pump, and any heater(s). The control box 602 receives information from appropriate sensors, and generally controls the overall operation of the deposition reactor. In certain example embodiments, the control box 602 controls driving a substrate web in an atomic layer deposition reactor from a first roll via a reaction space to a second roll. The control box 602 further controls exposing the reaction space to temporally separated precursor pulses to deposit material on said substrate web by sequential self-saturating surface reactions. The control box 602 may measure and relay probe readings from the deposition reactor to the HMI terminal 606. A dotted line 616 indicates an interface line between the deposition reactor parts and the control box 602.

Without limiting the scope and interpretation of the patent claims, certain technical effects of one or more of the example embodiments disclosed herein are listed in the following: A technical effect is adjusting an ALD reactor to a required production line substrate web speed. Another technical effect is longer service interval compared to for example spatial ALD reactors. Another technical effect is for example the placement of substrate web turning units outside of the reaction space into a cleaner environment so that the turning units will not be coated.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A method comprising:
receiving a moving substrate web into a reaction space of an atomic layer deposition reactor;
providing for the substrate web a track with a repeating pattern in the reaction space; and
exposing the substrate web to temporally separated precursor pulses in said reaction space to deposit material on said substrate web by sequential self-saturating surface reactions.

2. The method of claim 1, comprising:
turning the direction of propagation of the substrate web a plurality of times to form said repeated pattern.

3. The method of claim 1 or 2, comprising:
receiving the substrate web through an input gate that prevents gases from escaping from the reaction space.

4. The method of any preceding claim, comprising:
receiving the substrate web through an excess pressure hallway.

5. The method of any preceding claim, wherein said track with the repeating pattern forms flow channels within the reaction space, the method comprising:
using a flow distributor for said precursor pulses to reach each of said flow channels.

6. The method of claim 5, wherein said flow distributor comprises a flow spreader with a plurality of flow rakes with in-feed head openings.

7. The method of claim 6, comprising:
adjusting the length of the track within the reaction space by adjusting the track pattern.

8. An apparatus comprising:
an input gate configured to receive a moving substrate web into a reaction space of an atomic layer deposition reactor;
track forming elements configured to provide for the substrate web a track with a repeating pattern in the reaction space; and
a precursor vapor feeding part configured to expose the substrate web to temporally separated precursor pulses in said reaction space to deposit material on said substrate web by sequential self-saturating surface reactions.

9. The apparatus of claim 8, comprising:
turning units configured to turn the direction of propagation of the substrate web a plurality of times to form said repeated pattern.

10. The apparatus of claim 8 or 9, comprising:
an input gate configured to receive the substrate web therethrough into the reaction space, the input gate being configured to prevent gases from escaping from the reaction space.

11. The apparatus of claim 10, wherein the input gate comprises an excess pressure hallway through which the substrate web is configured to travel.

12. The apparatus of any preceding claim 8-11, wherein said track with the repeating pattern is configured to form flow channels within the reaction space, and the apparatus comprises:
a flow distributor for said precursor pulses to reach each of said flow channels.

13. The apparatus of claim 12, wherein said flow distributor comprises a flow spreader with a plurality of flow rakes with in-feed head openings.

14. A production line, comprising the apparatus of any preceding claim 8-14 configured to perform the method according to any preceding claim 1-7.

15. An apparatus comprising:
input means for receiving a moving substrate web into a reaction space of an atomic layer deposition reactor;
track forming means for providing for the substrate web a track with a repeating pattern in the reaction space; and
precursor vapor feeding means for exposing the substrate web to temporally separated precursor pulses in said reaction space to deposit material on said substrate web by sequential self-saturating surface reactions.
